(19) United States
(12) Patent Application Publication
(10) Pub. No.: US 2020/0343393 A1
(43) Pub. Date: Oct. 29, 2020

(54) ALKALI METAL-INCORPORATED CHALCOPYRITE COMPOUND-BASED THIN FILM AND METHOD OF FABRICATING THE SAME

(71) Applicant: KOREA INSTITUTE OF SCIENCE AND TECHNOLOGY, Seoul (KR)

(72) Inventors: Byoung Koun MIN, Seoul (KR); Yun Jeong HWANG, Seoul (KR); Hyung-Suk OH, Seoul (KR); Ung LEE, Seoul (KR); Dahye WON, Seoul (KR); Dong Ki LEE, Seoul (KR); Joo-Hyun KIM, Seoul (KR); Min Kyu KIM, Seoul (KR)

(21) Appl. No.: 16/397,334

(22) Filed: Apr. 29, 2019

(30) Foreign Application Priority Data
Apr. 25, 2019 (KR) 10-2019-0048606

(51) Int. Cl. H01L 31/0392; H01L 31/046

(52) U.S. Cl. CPC H01L 31/03923; H01L 31/022475; H01L 31/03928; H01L 31/046

(57) ABSTRACT

A chalcopyrite compound-based thin film in which an alkali metal is incorporated, and a method of fabricating the same are provided. The chalcopyrite compound-based thin film in which an alkali metal is incorporated may have improved film characteristics such as excellent chalcopyrite crystal characteristics and improved surface characteristics, and may exhibit improved optical characteristics by control of the distribution of constituent elements in the chalcopyrite compound layer. Accordingly, performance of a solar cell including the chalcopyrite compound-based thin film may be improved. The chalcopyrite compound-based thin film may be easily fabricated through a solution process.

### CROSS-REFERENCE TO RELATED APPLICATION

This application claims the benefit of Korean Patent Application No. 10-2019-0048606 filed on Apr. 25, 2019, in the Korean Intellectual Property Office, the disclosure of which is incorporated herein in its entirety by reference.

### BACKGROUND

### 1. Field

One or more embodiments relate to an alkali metal-incorporated chalcopyrite compound-based thin film and a method of fabricating the same.

### 2. Description of the Related Art

A photovoltaic device such as a solar cell is a device which converts solar energy to electrical energy. In particular, when light is incident onto a photosensitive material contained in such a photovoltaic cell, electrons and holes are generated by a photovoltaic effect to yield current and voltage. Since such a photovoltaic cell may obtain electrical energy from pollution-free solar energy, which is the source of all types of energy, much research has been conducted in this field with respect to alternative energy development.

Solar cells may be classified into various types depending on types of material used in a light absorption layer. Solar cell technologies currently in use include silicon (Si) solar cells (monocrystalline, polycrystalline, and amorphous silicon solar cells), compound solar cells (Group III-V GaAs, Group II-VI CdTe, and Group I-III-VI CIGS solar cells), and next-generation solar cells such as dye-sensitized solar cells, organic solar cells, and perovskite solar cells. Although it may be possible to manufacture flexible devices at a low cost with organic material-based next-generation solar cells, such solar cells are still in the research phase due to their low efficiency and their lack of stability over time and in different environments. Solar cells currently in the stage of commercialization are silicon solar cells and compound thin-film solar cells.

Although silicon solar cells advantageously have a high photoelectric conversion efficiency of about 25% to 26%, there also are drawbacks such as the need for a high-temperature process and costly manufacturing processes for control of silicon crystals and thin-film formation, a wide price fluctuation range varying depending on the supply and demand of silicon, and poor light absorption rate due to indirect band gap characteristics of silicon. Meanwhile, compound solar cells based on a chalcopyrite structure may have direct band gap characteristics and a large light absorption coefficient, making it possible to implement thin films and solar cells at lower costs, as compared with silicon solar cells.

Generally a compound solar cell may include a P-N junction with a p-type CIGS layer as a light absorption layer and an n-type buffer layer (mostly a CdS layer), wherein P-N junction-related characteristics are a significant factor determining solar cell efficiency. Currently, compound solar cells exhibit an efficiency of up to 22.6% [Phys. Status Solidi RRL 2016, 10, 583-586.], with performance being second only to silicon solar cells, but have limited price competitiveness due to manufacturing processes thereof involving simultaneous evaporation and sputtering processes under vacuum conditions. In this regard, to increase cost competitiveness, some research groups have made attempts to obtain a high-quality light absorption thin film by using solution processes using a low-cost chemical method. Solution processes may be applied in a variety of processes such as printing, roll-to-roll coating, and slot die coating processes, and also in the manufacture of larger-size devices and flexible devices. When solution processes are used, compound solar cells may be manufactured using a precursor solution or using a solution ink obtained by synthesizing and dispersing nanoparticles.

According to a method using a precursor solution, Cu₂S, In₂Se₃, Ga, Se, and S may be mixed with hydrazine to prepare a precursor solution, which may then be coated in multiple stages under a nitrogen atmosphere and thermally treated to thereby form a CIGS thin film. This method may provide an efficiency of up to 17.2%, which is close to that of a vacuum process [Energy Environ. Sci., 2016, 9, 3674˜3681, Prog. Photovolt: Res. Appl. 2013; 21:82-87]. For example, a nitrate or hydrate composite may be dissolved in a methanol solution to prepare a precursor solution (Cu(NO₃)₂.xH₂O, In(NO₃)₃.xH₂O, and Ga(NO₃)₃.xH₂O), which may then be subjected to multi-stage coating, annealing, and selenization under a sulfur (S) atmosphere to thereby form a CIGS thin film, with an efficiency of up to 14.5% (ACS Appl. Mater. Interfaces 2018, 10, 9894-9899). Although the latter process exhibits a slightly lower efficiency than the former process, it has been suggested as an alternative to a process using hydrazine, since hydrazine is highly toxic and explosive such that safety and stability are not ensured. As another alternative to hydrazine, it may be possible to use nano ink, wherein a metal chloride, a thiourea surfactant, and a dimethyl sulfoxide solvent may be used, and through selenization an efficiency of 14.7% may be obtained (Energy Environ. Sci., 2016, 9, 130-134).

Though a compound thin-film solar cell manufactured by a solution process exhibits considerably increased efficiency, this efficiency level is still lower than that obtained by a vacuum process, which is known to be due to the reduced density of thin films. In a thin film formed by vacuum deposition, chalcopyrite crystals may be formed over the entire thin film with almost no pores. However, in a thin film formed by solution process, the evaporation of solvents or organic additives during a thermal treatment process causes the generation of a large number of pores. However, such organic materials may interfere with efficient selenization, such that selenium cannot efficiently penetrate into a lower part of the thin film, and chalcopyrite crystals are concentrated only in an upper part of the thin film and not properly generated in the lower part. In a solution process of the related art, specific elements may be concentrated in certain regions of the thin film, and the concentration distribution of elements may be not properly controlled.

Therefore, there is a need for the development of a solution process capable of reducing an efficiency gap between solution and vacuum processes and improving performance of a solar cell.

### SUMMARY

One or more embodiments include a chalcopyrite compound-based thin film in which an alkali metal is incorporated to improve the performance of a solar cell fabricated by using a solution process.

One or more embodiments include a solar cell including the chalcopyrite compound-based thin film.

One or more embodiments include a method of forming the chalcopyrite compound-based thin film.

Additional aspects will be set forth in part in the description which follows and, in part, will be apparent from the description, or may be learned by practice of the presented embodiments.

According to one or more embodiments, a chalcopyrite compound-based thin film includes: a substrate; a chalcopyrite compound layer as a monolayer or multiple layers on the substrate; and an alkali metal layer located inside or on top of the chalcopyrite compound layer.

According to one or more embodiments, a solar cell includes the chalcopyrite compound-based thin film.

According to one or more embodiments, a method of fabricating a chalcopyrite compound-based thin film includes: applying a first metal precursor paste onto a substrate and thermally treating the applied first metal precursor paste to form a first metal oxide thin film; applying an alkali precursor solution onto the first metal oxide thin film and thermally treating the applied alkali precursor solution to form an alkali metal layer; applying a second metal precursor paste onto the alkali metal layer and thermally treating the applied second metal precursor paste to form a second metal oxide thin film; and thermally treating a stack of the first metal oxide thin film, the alkali metal layer and the second metal oxide thin film under an atmosphere of a sulfur precursor in a gas state, a selenium precursor in a gas state, or a mixture thereof.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view illustrating a method of fabricating a copper indium gallium selenide (CIGS) thin film by incorporation of a potassium (K) layer, according to an embodiment:

FIG. 2 illustrates X-ray diffraction (XRD) patterns of a CIGS thin film fabricated by incorporation of K (0.8 wt %) according to Example 1;

FIG. 3 is a cross-sectional scanning electron microscope (SEM) image of a CIGS thin film fabricated without incorporation of potassium (K) according to Comparative Example 1;

FIG. 4 is a cross-sectional SEM image of a CIGS thin film fabricated by incorporation of K (0.8%) according to Example 1;

FIG. 5 is a graph illustrating changes in a concentration ratio of gallium (Ga) to a total concentration of indium (In) and Ga in CIGS thin films fabricated in Example 1 and Comparative Example 1, and band gap values calculated from the element concentration change values;

FIG. 6 illustrates the current density-voltage (J-V) curves of solar cells of Examples 4 to 6 and Comparative Example 2 using CIGS thin films formed in Examples 1 to 3 and Comparative Example 1, respectively; and

FIG. 7 is a graph illustrating results of external quantum efficiency (EQE) analysis of the solar cells of Example 4 and Comparative Example 2 using the CIGS thin films formed in Example 1 and Comparative Example 1, respectively.

### DETAILED DESCRIPTION

The present inventive concept will now be described more fully with reference to the accompanying drawings, in which example embodiments are shown. The present inventive concept may, however, be embodied in many different forms, should not be construed as being limited to the embodiments set forth herein, and should be construed as including all modifications, equivalents, and alternatives within the scope of the present inventive concept; rather, these embodiments are provided so that this inventive concept will be thorough and complete, and will fully convey the effects and features of the present inventive concept and ways to implement the present inventive concept to those skilled in the art.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The sign “/” used herein may be construed as meaning of “and” or “or” depending on the situation.

In the drawings, the size or thickness of each layer, region, or element are arbitrarily exaggerated or reduced for better understanding or ease of description, and thus the present inventive concept is not limited thereto. Throughout the written description and drawings, like reference numbers and labels will be used to denote like or similar elements. It will also be understood that when an element such as a layer, a film, a region or a component is referred to as being “on” another layer or element, it can be “directly on” the other layer or element, or intervening layers, regions, or components may also be present. Although the terms “first”, “second”, etc., may be used herein to describe various elements, components, regions, and/or layers, these elements, components, regions, and/or layers should not be limited by these terms. These terms are used only to distinguish one component from another, not for purposes of limitation.

It will be understood that, although the terms first, second, third, etc., may be used herein to describe various elements, components, regions, layers and/or sections, these elements, components, regions, layers and/or sections should not be limited by these terms.

In regard to manufacturing processes described herein, the manufacturing processes may not be carried out in the stated order. For example, in cases where a first step and a second step are described, it will be understood that the first step does not necessarily precede the second step.

Hereinafter, embodiments of an alkali metal-incorporated chalcopyrite compound-based thin film and a method of fabricating the same will be described in greater detail.

According to an aspect of the disclosure, a chalcopyrite compound-based thin film includes: a substrate; a chalcopyrite compound layer as a monolayer or multiple layers on the substrate; and an alkali metal layer arranged inside or on top of the chalcopyrite compound layer.

The substrate may be a conductive substrate or a substrate in which a conductive material is coated on a non-conductive substrate. For example, the substrate may be a conductive substrate including at least one of indium tin oxide, a fluorine-doped indium tin oxide, glass, molybdenum (Mo)-coated glass, metal foil, metal plate, and a conductive polymer material; or a substrate in which one or a mixture of at least two of indium tin oxide, fluorine-doped indium tin oxide, glass, molybdenum (Mo)-coated glass, metal foil, metal plate, and a conductive polymer material is coated on a non-conductive substrate.

The chalcopyrite compound layer may include an inorganic compound having a chalcopyrite crystal structure consisting of Group I, III, and VI elements. The inorganic compound may include a Group IB element, a Group IIIA element, and a Group VIA element. The Group IB element may include copper (Cu), the Group IIIB element may include at least one of indium (In) and gallium (Ga), and the Group VIA element may include at least one of selenium (Se) and sulfur (S).

In one or more embodiments, the chalcopyrite compound layer may include at least one inorganic compound of a copper indium selenide (CISe)-based compound, a copper indium gallium selenide (CIGSe)-based compound, a copper indium sulfide (CIS)-based compound, a copper indium gallium sulfide (CIGS)-based compound, and a copper indium gallium sulfur selenide (CIGSSe)-based compound.

In one or more embodiments, the inorganic compound having a chalcopyrite crystal structure may include CuInₓGa₍₁₋ₓ₎S_{y}Se_{(2-y)} (wherein 0≤x≤1 and 0≤y≤2).

The chalcopyrite compound layer may be a single layer or a multilayer structure of at least two layers. A total thickness of the chalcopyrite compound layer may be about 0.01 μm to about 20 μm, for example, about 0.1 μm to about 5 μm or about 0.5 μm to about 3 μm. Within these thickness ranges, improved optical characteristics may be exhibited.

The alkali metal layer may be arranged inside or on top of the chalcopyrite compound layer. When an alkali metal layer is incorporated, chalcopyrite crystal characteristics may be significantly improved.

The alkali metal, which is a chemical element belonging to Group I of the periodic table of elements, except for hydrogen (H), may be at least one selected from the group consisting of lithium (Li), sodium (Na), potassium (K), rubidium (Rb), cesium (Cs), and francium (Fr). In one or more embodiments, the alkali metal may be potassium (K).

In one or more embodiments, the alkali metal layer may have a thickness of about 1 nm to about 500 nm. When the alkali metal layer has a thickness within these thickness ranges, the chalcopyrite compound-based thin film may have improved optical characteristics.

In one or more embodiments, the amount of the alkali metal layer may be in a range of about 0.1 wt % to about 30 wt % based on a total weight of the chalcopyrite compound layer and the alkali metal layer. Within these ranges, improved chalcopyrite crystal characteristics and improved optical characteristics of the chalcopyrite compound-based thin film may be exhibited.

In one or more embodiments, when the alkali metal layer is in the chalcopyrite compound layer, a concentration distribution of at least one of In, Ga, Cu, S, and Se in upper and lower regions of the chalcopyrite compound layer may be different from that in a central region thereof. For example, the concentration of at least one of In, Ga, Cu, S, and Se in the upper and lower regions of the chalcopyrite compound layer may vary within a range of about 0.0001 times to about 500 times with respect to that in the central region thereof. By the compositional change of each element in a depth direction of the chalcopyrite compound layer, a band gap grading structure may be changed.

By the introduction of the alkali metal layer as described above into the chalcopyrite compound-based thin film, chalcopyrite crystal characteristics and surface characteristics of the chalcopyrite compound layer may be improved. By control of the distribution of an alkali metal, the chalcopyrite compound-based thin film may have improved optical characteristics. When such a chalcopyrite compound-based thin film is applied to a solar cell, it may be possible to implement highly efficient, low-cost solar cell characteristics.

According to another aspect of the disclosure, a solar cell includes the chalcopyrite compound-based thin film according to any of the embodiments.

According to another aspect of the disclosure, there is provided a method of fabricating a chalcopyrite compound-based thin film in which an alkali metal is incorporated, by using a solution process.

In one or more embodiments, the method of fabricating the chalcopyrite compound-based thin film may include:

applying a first metal precursor paste onto a substrate and thermally treating the applied first metal precursor paste to form a first metal oxide thin film;

applying an alkali precursor solution onto the first metal oxide thin film and thermally treating the applied alkali precursor solution to form an alkali element layer;

applying a second metal precursor paste onto the alkali element layer and thermally treating the applied second metal precursor paste to form a second metal oxide thin film; and

thermally treating a stack of the first metal oxide thin film, the alkali element layer and the second metal oxide thin film under an atmosphere of a sulfur precursor in a gas state, a selenium precursor in a gas state, or a mixture thereof.

The first metal precursor paste and the second metal precursor paste may each independently include a metal precursor, an organic binder and a solvent.

A first metal precursor in the first metal precursor paste and a second metal precursor in the second metal precursor paste may be the same or differ from each other. The first metal precursor and the second metal precursor may each independently include at least one Group IB metal precursor, at least one Group IIIA metal precursor, or a mixture thereof.

Each of the metal precursors capable of forming ions of a metal may be in the form of a nitrate, a hydrate, a chloride, a hydroxide, a sulfate, an acetate, an acetylacetonate, a formate, or an oxide of a metal or an alloy of at least two metals. Each metal precursor paste may be prepared using the same compound or at least two compounds selected from these metal precursors.

In one or more embodiments, the first metal precursor and the second metal precursor may each independently include a Cu compound, an In compound, and/or a Ga compound. In each of the first metal precursor paste and the second metal precursor paste, a ratio of (concentration of Cu element) to (a total concentration of In element and Ga element) may be in a range of about 1:0.9-1.3, and a ratio of (concentration of Ga element) to (a total concentration of In element and Ga element) may be in a range of about 1:2.5-4. Within these concentration ranges, a CIG oxide thin film having a desired composition may be obtained.

A first organic binder in the first metal precursor paste and a second organic binder in the second metal precursor paste may be the same or differ from each other. The first organic binder and the second organic binder may each independently include one or a mixture of at least two of ethyl cellulose, polyvinyl acetate, palmitic acid, polyethylene glycol, polypropylene glycol, polypropylene carbonate, and propylene diol. An amount of each organic binder in a metal precursor paste may be in a range of about 0.1 parts to about 30 parts by weight with respect to 100 parts by weight of the metal precursor. When the amount of an organic binder is within this range, the binding strength of metal particles in the chalcopyrite compound layer and internal density thereof may be increased.

A first solvent included in the first metal precursor paste and a second solvent included in second metal precursor paste may be the same or different from each other. The first solvent and the second solvent may each independently include one or at least two of water, methanol, ethanol, propanol, butanol, acetone, dimethyl ketone, propanone, methoxyethane, ethoxyethane, 1,2-dimethoxyethane, benzene, toluene, xylene, tetrahydrofuran, anisole, hexane, cyclohexane, carbon tetrachloride, methylene chloride, and chloroform.

The first metal precursor paste and the second metal precursor paste may each independently have a viscosity of about 50 cP to about 1,500 cP. When the first and second metal precursor paste each independently have a viscosity within this range, the internal density and surface flatness of each thin film may be ensured when the paste is coated. By controlling the amount of each solvent, the viscosity of each metal precursor may be controlled to be within this range.

The substrate may be a conductive substrate or a substrate in which a conductive material is coated on a non-conductive substrate. For example, the substrate may be a conductive substrate including one or at least two of indium tin oxide, a fluorine-doped indium tin oxide, glass, molybdenum (Mo)-coated glass, metal foil, metal plate, and a conductive polymer material; or a substrate in which one or a mixture of at least two of indium tin oxide, fluorine-doped indium tin oxide, glass, molybdenum (Mo)-coated glass, metal foil, metal plate, and a conductive polymer material is coated on a non-conductive substrate.

Prior to the forming of the first metal oxide thin film on the substrate, impurities on a surface of the substrate may be removed by, for example, ultrasonic washing.

The first metal precursor paste may be applied onto the substrate prepared as described above and then thermally treated to form the first metal oxide thin film. The application and thermal treatment of the first metal precursor paste may be performed one to 20 times. When multi-stage coating of at least two times is performed, the first metal precursor paste for each coating may be prepared to have the same composition or different compositions. The application may be performed using one or at least two methods of printing, spin coating, roll-to-roll coating, slot die coating, bar coating, and spray coating. After the coating of the first metal precursor paste, the thermal treatment may be performed under air atmosphere at a temperature of about 250° C. to about 350° C. for about 1-60 minutes. As a result, the first metal oxide thin film as a single layer to 20 layers may be formed on the substrate.

Next, an alkali precursor solution may be coated on the first metal oxide thin film and then thermally treated to form the alkali element layer.

An alkali precursor included in the alkali precursor solution may include, for example, at least one of fluoride, chloride, hydroxide, bromide, iodide, nitrate, perchlorate, carbonate, and sulfate compounds of an alkali element. The alkali precursor is not limited to the above-listed alkali precursors, and may be any of a variety of compounds. Although an alkali metal is known as a chemical element pertaining to Group I of the periodic table of elements, except for hydrogen (H), the alkali metal may be at least one selected from the group consisting of lithium (Li), sodium (Na), potassium (K), rubidium (Rb), cesium (Cs), and francium (Fr). In one or more embodiments, the alkali metal may be potassium (K).

The alkali precursor solution may include at least one solvent selected from water, methanol, ethanol, propanol, butanol, acetone, dimethyl ketone, propanone, methoxyethane, ethoxyethane, 1,2-dimethoxyethane, benzene, toluene, xylene, tetrahydrofuran, anisole, hexane, cyclohexane, carbon tetrachloride, methylene chloride, and chloroform.

An amount of the alkali precursor in the alkali precursor solution may be about 0.01 wt % to about 50 wt % based on a total weight of the alkali precursor solution. Within this range, it may be easy to dissolve and coat the alkali precursor.

The alkali precursor may be used as a mixture with at least one of Cu, In, and Ga metal precursors used in preparation of a chalcopyrite compound.

The application of the alkali precursor solution may be performed using one or at least two methods of printing, spin coating, roll-to-roll coating, slot die coating, bar coating, and spray coating.

After the application of the alkali precursor solution, the thermal treatment may be performed under air atmosphere at a temperature of about 100° C. to about 300° C. By the thermal treatment, the alkali metal layer may be formed on the first metal oxide thin film.

The application and thermal treatment of the alkali precursor solution on the first metal oxide thin film may be performed one to 20 times. An application amount and the number of applications of the alkali precursor solution may be determined such that an amount of the alkali metal layer is in a range of 0.1 wt % to about 30 wt % based on a total weight of the chalcopyrite compound layer and the alkali metal layer in the chalcopyrite compound-based thin film as a final product. In one or more embodiments, the alkali precursor solution may be coated on the first metal oxide thin film in an amount of about 0.001 parts to about 30 parts by weight with respect to 100 parts by weight of the first metal precursor paste.

After the formation of the alkali element layer, the second metal precursor paste may be coated on the alkali element layer and then thermally treated to form the second metal oxide thin film.

The above-described application and thermal treatment process of the first metal precursor paste may apply to the application and thermal treatment of the second metal precursor paste.

The application and thermal treatment of the second metal precursor paste may be performed one to 20 times. When multi-stage coating of at least two times is performed, the second metal precursor paste for each coating may be prepared to have the same composition or different compositions. The application may be performed using one or at least two methods of printing, spin coating, roll-to-roll coating, slot die coating, bar coating, and spray coating. After the application of the second metal precursor paste, the thermal treatment may be performed under air atmosphere at a temperature of about 250° C. to about 350° C. for about 1-60 minutes. As a result, the second metal oxide thin film as a single layer to 20 layers may be formed on the alkali element layer.

The thus-formed stack of the first metal oxide thin film, the alkali element layer, and the second metal oxide tin film may be thermally treated under an atmosphere of a sulfur precursor in a gas state, a selenium precursor in a gas state, or a mixed thereof, to proceed sulfurization and/or selenization of the first metal oxide thin film and the second metal oxide thin film to thereby obtain a crystalline chalcopyrite structure consisting of Group I, Group III, and Group VI elements.

For example, the sulfur precursor may be a sulfur (S) element or a sulfur-containing organic compound, for example, H₂S, alkyl thiol (RSH, wherein R is a C1-10 alkyl or carboxyl alkyl group), thiourea, or thioacetamide. However, embodiments are not limited thereto.

For example, the selenium precursor may be Na₂Se, Na₂SeO₃, Na₂SeO₃.5H₂O, or Se, which may provide negative or neutral Se ions in a solvent; SeCl₄ or SeS₂, which may provide positive Se ions; or the element Se. However, embodiments are not limited thereto.

The sulfurization and/or selenization may be implemented by thermal treatment in a gaseous atmosphere of, for example, H₂S, S vapor, H₂Se, Se vapor, or a mixed gas thereof, or by thermal treatment in a mixed gas atmosphere of these gases and an inert gas. The sulfurization and/or selenization may be performed under a vapor atmosphere created using S powder or Se powder.

The thermal treatment temperature for the sulfurization and/or selenization may be about 50° C. to about 1500° C., for example, about 400° C. to about 900° C., or about 400° C. to about 600° C. The thermal treatment may be performed in a single temperature mode or a multistage temperature mode.

In one or more embodiments, instead of the separate application of the alkali precursor solution, a method of directly incorporating an alkali element or alkali precursor in the first or second metal precursor paste may be used. In this case, a method of fabricating the chalcopyrite compound-based thin film according to one or more embodiments may include applying a metal precursor paste onto a substrate and thermally treating the applied metal precursor paste to form a metal oxide thin film; and thermally treating the metal oxide thin film under an atmosphere of a sulfur precursor in a gas state, a selenium precursor in a gas state, or a mixture thereof, wherein the metal precursor paste may include at least one Group IB metal precursor or at least one Group IIIA metal precursor or a mixture of at least two thereof; and an alkali element or an alkali precursor.

As described above, through the thermal treatment and the sulfurization and/or selenization, the alkali element or alkali precursor in the metal precursor, the chalcopyrite compound-based thin film according to one or more embodiments in which the alkali element layer is inside or on top of the chalcopyrite compound layer may be obtained.

In one or more embodiments, a method of fabricating the chalcopyrite compound-based thin film according to one or more embodiments may include: applying a first metal precursor paste onto a substrate and thermally treating the applied first metal precursor paste to form a first metal oxide thin film; applying a second metal precursor paste onto the first metal oxide thin film and thermally treating the applied second metal precursor paste to form a second metal oxide thin film; and thermally treating a stack of the first metal oxide thin film and the second metal oxide thin film under an atmosphere of a sulfur precursor in a gas state, a selenium precursor in a gas state, or a mixture thereof, wherein the first metal precursor paste and the second metal precursor paste each independently may include at least one Group IB metal precursor or at least one Group IIIA metal precursor or a mixture of at least two thereof, and the second metal precursor paste may further include an alkali precursor.

In this case, when forming the second metal oxide thin film after the first metal oxide thin film is formed on the substrate, an alkali element or alkali precursor may be directly incorporated into the second metal precursor paste, so that the arrangement of the alkali element layer in the chalcopyrite compound-based thin film may be controlled.

One or more embodiments of the present disclosure will now be described in detail with reference to the following examples. However, these examples are only for illustrative purposes and are not intended to limit the scope of the one or more embodiments of the present disclosure.

### Example 1: Fabrication of Alkali Element (0.8 wt % Based on Precursors)-Incorporated CIGS Thin Film

1 g (5 mmol) of Cu(NO₃)₂.xH₂O, 1.15 g (3.7 mmol) of In(NO₃)₃.xH₂O, and 0.49 g (1.6 mmol) of Ga(NO₃)₃.xH₂O were mixed in 8 mL of a methanol solvent to prepare a CIG precursor solution. A polymer binder solution was prepared by dissolving polyvinyl alcohol (having a molecular weight of 100,000 g/mol) in a methanol solvent with stirring for about 2 hours. The two solutions were mixed together with stirring at room temperature for about 30 minutes, and then filtered through a syringe filter (PTFE, 0.2-μm pore size, Whatman) to remove impurities, thereby completing a CIG precursor mixture paste.

Molybdenum (Mo) was deposited on a soda-lime glass with a DC sputter to a thickness of about 500 nm to prepare a conductive Mo-glass substrate. The substrate was sonicated in a washing solution, deionized water, acetone, and then isopropyl alcohol each for 10 minutes, and then dried using a nitrogen gun. Next, the CIG precursor mixture paste was spin-coated on the Mo-glass substrate at about 2000 rpm for about 40 seconds, and dried on a hot plate at about 300° C. for about 30 minutes to form a CIG oxide thin film (having a thickness of about 1 μm).

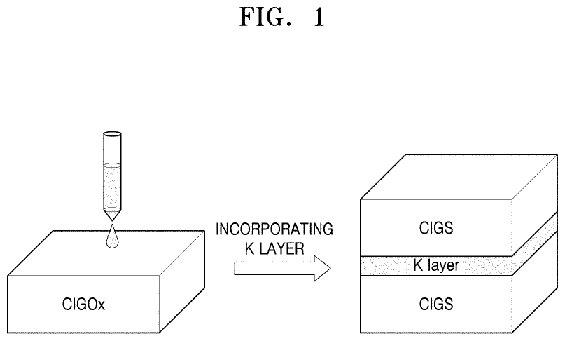

Meanwhile, 0.08 g of KF was dissolved and ionized in 8 mL of a methanol solvent to prepare an alkali precursor solution. After repeating the coating of the CIG precursor mixture paste and the thermal treatment twice more to form a three-layered CIG oxide thin film, the alkali precursor solution was spin-coated on the thin film and thermally treated to form the thin film having a thickness of about 20 nm. Then, the CIG precursor mixture paste was spin-coated on the alkali precursor solution-coated thin film and then thermally treated. The spin coating and the thermal treatment were repeated three times more, thereby completing a 7-layered CIG oxide thin film as illustrated in FIG. 1.

After the obtained CIG oxide thin film was put into a furnace containing selenium pellets, a sulfur vapor atmosphere was created and the temperature of the furnace was increased to about 400° C. over 30 minutes and then to about 500° C. over 30 minutes such that a selenium vapor atmosphere was created. In these processes a CIGS thin film was obtained by selenization of the CIG precursor oxide thin film. As a result of inductively coupled plasma (ICP) analysis, the CIGS thin film was found to have a K content of about 0.6 wt %.

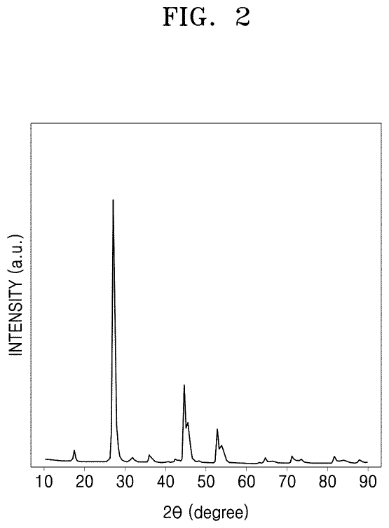

A crystalline structure of the CIGS thin film was identified from X-ray diffraction (XRD) patterns. The results are shown in FIG. 2. Referring to the XRD pattern of the CIGS thin film in FIG. 2, the CIGS thin film was found to have a highly developed chalcopyrite structure. The XRD pattern analysis was performed using a D8 Advance X-ray diffractormeter (available from Bruker).

### Example 2: Fabrication of Alkali Element (1.6 wt % Based on Precursors)-Incorporated CIGS Thin Film

A CIGS thin film was formed in the same manner as in Example 1, except that 0.16 g of KF was dissolved and ionized in 8 mL of a methanol solvent to prepare an alkali precursor solution.

### Example 3: Fabrication of Alkali Element (2.4 wt % Based on Precursors)-Incorporated CIGS Thin Film

A CIGS thin film was formed in the same manner as in Example 1, except that 0.24 g of KF was dissolved and ionized in 8 mL of a methanol solvent to prepare an alkali precursor solution.

### Comparative Example 1: Fabrication of No Alkali Element-Incorporated CIGS Thin Film

A CIGS thin film was formed in the same manner as in Example 1, except that an alkali element was not incorporated.

### Evaluation Example 1: Scanning Electron Microscopy (SEM) Analysis

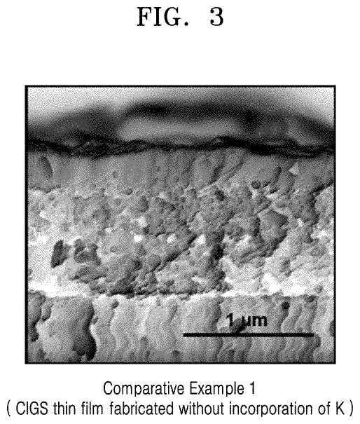

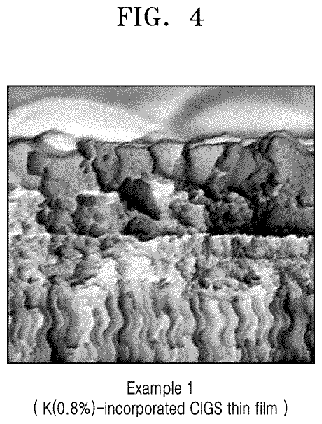

The CIGS thin films obtained in Comparative Example 1 (no alkali element introduce) and Example 1 (0.8% of alkali element incorporated) were analyzed by SEM. The obtained cross-sectional SEM images of the CIGS thin films according to Comparative Example 1 and Example 1 are shown in FIGS. 3 and 4, respectively. Referring to FIGS. 3 and 4, the K-incorporated CIGS thin film (Example 1) was found to have a well-formed thicker upper layer as compared with that of the CIGS thin film (Comparative Example 1) prepared without the incorporation of K.

### Evaluation Example 2: Inductively Coupled Plasma (ICP) Analysis

The CIGS thin films of Example 1 and Comparative Example 1 were analyzed by ICP. The results are shown in Table 1.

TABLE 1

Element content (wt %)

| | In | Ga | S | Se | Cu | K |
|---|---|---|---|---|---|---|
| Comparative | 34.9 | 0.8 | 10.7 | 32.2 | 21.4 | — |
| Example 1 | | | | | | |
| (0% of K) | | | | | | |
| Example 1 | 33.8 | 0.8 | 8.0 | 35.0 | 21.8 | 0.6 |
| (0.8% of K) | | | | | | |

Referring to Table 1, as a result of the ICP analysis, the CIGS thin film of Example 1 was found to have a higher selenium (Se) content (wt %), as compared with the CIGS thin film of Comparative Example 1, indicating that more efficient selenization occurred due to the incorporation of the alkali element, consequently leading to the formation of the thicker upper layer in the CIGS thin film of Example 1, as compared with that of Comparative Example 1,

### Evaluation Example 3: Calculation of Element Concentration Change Values and Band Gap Values

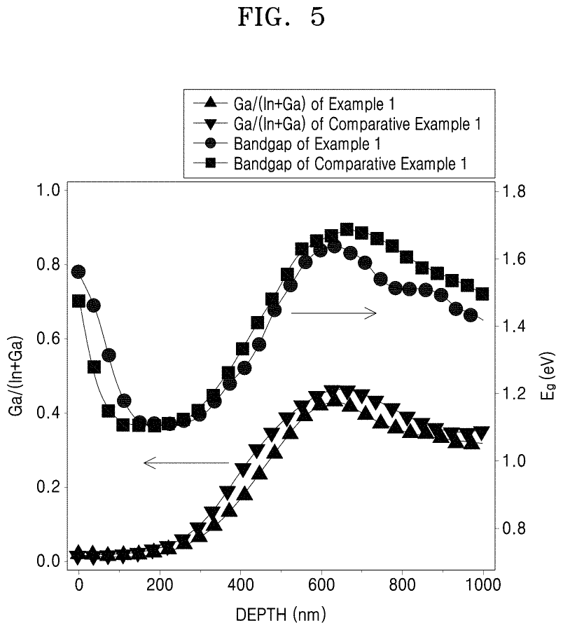

A concentration ratio of gallium (Ga) to total concentration of indium (In) and Ga in each of the CIGS thin films of Example 1 and Comparative Example 1, and band gap values calculated therefrom are shown in FIG. 5.

Referring to FIG. 5, the CIGS thin film of Example 1 fabricated by the incorporation of the alkali element was found to have a reduced Ga to (In+Ga) ratio and a reduced lowest band gap value, as compared with that of Comparative Example 1. These results are attributed to that the distribution of elements was efficiently controlled through rearrangement of the elements by the incorporation of the alkali element.

### Example 4: Solar Cell Using CIGS Thin Film Fabricated in Example 1

A CIGS thin-film solar cell was manufactured using the CIGS thin film of Example 1 as a light absorption layer.

First, a CdS buffer layer was formed on the CIGS thin film of Example 1 by chemical bath deposition (CBD) as follows. After cadmium sulfate (CdSO₄) was dissolved in 440 mL of deionized water and 65 mL of an ammonia solution (NH₄OH, 30%), the Mo-glass substrate having the CIGS thin film was dipped into the cadmium sulfate solution in a 65° C. water bath for about 10 minutes, removed therefrom, and then washed with deionized water. The washed CIGS thin film was then dipped into a potassium cyanide (KCN) solution (1.6M) for about 1 minute and then washed with deionized water to remove secondary phases, thereby forming the CdS buffer layer. Then, i-ZnO (50-nm thick) and Al-doped ZnO (Al:ZnO) (550-nm thick) were deposited on the CdS buffer layer by RF sputtering to form a window layer. Then, Ni (50 nm) and Al (500 nm) upper electrodes were deposited thereon by e-beam deposition with a stainless steel mask to thereby complete fabrication of a CIGS thin-film solar cell. The area of the light absorption layer was defined to be about 0.25 cm² by mechanical scribing.

### Example 5: Solar Cell Using the CIGS Film Fabricated in Example 2

A CIGS thin-film solar cell was manufactured in the same manner as in Example 4, except that the CIGS thin film obtained in Example 2 was used as the light absorption layer.

### Example 6: Solar Cell Using the CIGS Film Fabricated in Example 3

A CIGS thin-film solar cell was manufactured in the same manner as in Example 4, except that the CIGS thin film obtained in Example 3 was used as the light absorption layer.

### Comparative Example 2: Solar Cell Using the CIGS Film Fabricated in Comparative Example 1

A CIGS thin-film solar cell was manufactured in the same manner as in Example 4, except that the CIGS thin film obtained in Comparative Example 1 was used as the light absorption layer.

### Evaluation Example 4: Performance Evaluation of CIGS Thin Film

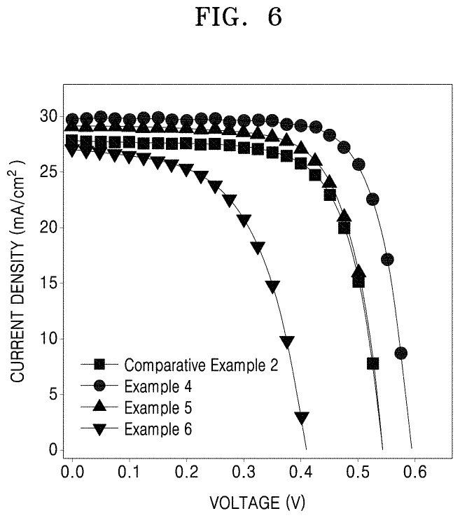

The current density-voltage (J-V) curves of the CIGS thin-film solar cells of Examples 4-6 and Comparative Example 2 are shown in FIG. 6. The J-V curves were obtained with a CompactStat potentiostat (Ivium Technologies, The Netherlands) and analyzed using a Sun 2000 solar simulator (ABET Technologies, U.S.A) under 1 SUN (100 mW/cm²) conditions.

The current densities (J_{sc}), voltages (V_{oc}), fill factors (FF), and photovoltaic efficiencies (PCE) calculated from the J-V curves of FIG. 6 are shown in Table 2.

TABLE 2

| | K content on | | | | |
|---|---|---|---|---|---|
| | precursor | V_{oc} | J_{sc} | FF | PCE |
| Example | basis (wt %) | [V] | [mA · cm⁻²] | [%] | [%] |
| Comparative | 0 | 0.55 | 27.7 | 68.5 | 10.4 |
| Example 2 | | | | | |
| Example 4 | 0.8 | 0.59 | 29.6 | 71.7 | 12.5 |
| Example 5 | 1.6 | 0.55 | 29.0 | 70.5 | 11.2 |
| Example 6 | 2.4 | 0.41 | 27.0 | 52.6 | 5.8 |

Referring to FIG. 6 and Table 2, the K (0.8 wt %)-incorporated CIGS solar cell of Example 4 was found to have improved performance in terms of V_{oc}, J_{sc}, and FF characteristics, as compared with the CIGS solar cell of Comparative Example 2 fabricated without incorporation of K. The CIGS solar cell of Example 5 in which 1.6 wt % of K was incorporated was also found to have improved performance, as compared with the solar cell of Comparative Example 2 in which K was not incorporated. However, when the K content was increased to 2.4 wt % of Example 6, the performance of the solar cell was found to deteriorate, as compared with the solar cell of Comparative Example 2. This is attributed to an excessive amount of K being added such that it aggregated and acted like an impurity, hindering charge transfer.

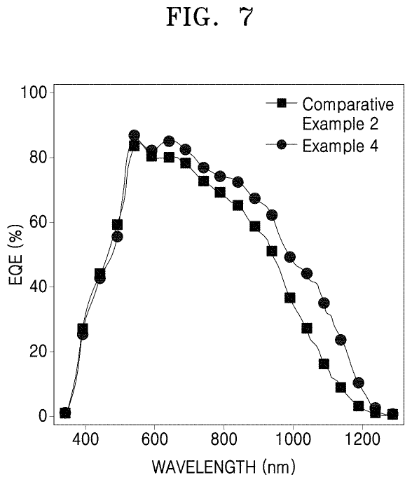

To help understanding of the improvement in current density (J_{sc}), external quantum efficiencies (EQEs) of the CIGS thin-film solar cells of Example 4 and Comparative Example 2 were analyzed through photon-to-current conversion efficiency measurements. The results are shown in FIG. 7.

Referring to FIG. 7, the K(0.8%)-incorporated CIGS thin-film solar cell was found to exhibit an increased EQE ever a wide wavelength region including long wavelengths, as compared with the CIGS thin-film solar cell of Comparative Example 2 manufactured without the incorporation of K, indicating that a CIGS solar cell may have improved performance by incorporation of K.

As described above, according to the one or more embodiments, a chalcopyrite compound-based thin film in which an alkali element is incorporated may have improved film characteristics such as excellent chalcopyrite crystal characteristics and improved surface characteristics, and may exhibit improved optical characteristics by control of the distribution of constituent elements in the chalcopyrite compound-based thin film. Accordingly, performance of a solar cell including the chalcopyrite compound-based thin film may be improved. The chalcopyrite compound-based thin film may be easily fabricated through a solution process.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the disclosure as defined by the following claims.

What is claimed is:

1. A chalcopyrite compound-based thin film comprising:
a substrate;
a chalcopyrite compound layer as a monolayer or multiple layers on the substrate; and
an alkali metal layer located inside or on top of the chalcopyrite compound layer.

2. The chalcopyrite compound-based thin film of claim 1, wherein the alkali metal layer comprises at least one element selected from the group consisting of lithium (Li), sodium (Na), potassium (K), rubidium (Rb), cesium (Cs), and francium (Fr).

3. The chalcopyrite compound-based thin film of claim 1, wherein the alkali metal layer has a thickness of about 1 nm to about 500 nm.

4. The chalcopyrite compound-based thin film of claim 1, wherein an amount of the alkali metal layer is about 0.01 wt % to about 30 wt % based on a total weight of the chalcopyrite compound layer and the alkali metal layer.

5. The chalcopyrite compound-based thin film of claim 1, wherein the chalcopyrite compound layer comprises an inorganic compound having a chalcopyrite crystal structure consisting of Group II, III, and VI elements.

6. The chalcopyrite compound-based thin film of claim 5, wherein the inorganic compound comprises at least one of a copper indium selenide (CISe)-based compound, a copper indium gallium selenide (CIGSe)-based compound, a copper indium sulfide (CIS)-based compound, a copper indium gallium sulfide (CIGS)-based compound, and a copper indium gallium sulfur selenide (CIGSSe)-based compound.

7. The chalcopyrite compound-based thin film of claim 1, wherein a concentration distribution of at least one of In, Ga, Cu, S, and Se in upper and lower regions of the chalcopyrite compound layer is different from that in a central region of the chalcopyrite compound layer.

8. The chalcopyrite compound-based thin film of claim 7, wherein the concentration of at least one of In, Ga, Cu, S, and Se in the upper and lower regions of the chalcopyrite compound layer varies within a range of about 0.0001 times to about 500 times with respect to that in the central region thereof.

9. The chalcopyrite compound-based thin film of claim 1, wherein the chalcopyrite compound layer has a band gap grading structure varying in a depth direction of the chalcopyrite compound layer.

10. The chalcopyrite compound-based thin film of claim 1, wherein the substrate comprises at least one of indium tin oxide, fluorine-doped indium tin oxide, glass, molybdenum (Mo)-coated glass, metal foil, metal plate, and a conductive polymer material.

11. A solar cell comprising the chalcopyrite compound-based thin film according to claim 1.

12. A method of fabricating a chalcopyrite compound-based thin film, the method comprising:
applying a first metal precursor paste onto a substrate and thermally treating the applied first metal precursor paste to form a first metal oxide thin film;
applying an alkali precursor solution onto the first metal oxide thin film and thermally treating the applied precursor solution to form an alkali metal layer;
applying a second metal precursor paste onto the alkali metal layer and thermally treating the applied second metal precursor paste to form a second metal oxide thin film; and
thermally treating a stack of the first metal oxide thin film, the alkali metal layer, and the second metal oxide thin film under an atmosphere of a sulfur precursor in a gas state, a selenium precursor in a gas state, or a mixture thereof.

13. The method of claim 12, wherein the first metal precursor paste and the second metal precursor paste each independently comprise a metal precursor, an organic binder, and a solvent.

14. The method of claim 13, wherein the metal precursor comprises at least one Group IB metal precursor, at least one Group IIIA metal precursor, or a mixture thereof.

15. The method of claim 13, wherein the organic binder comprises one or a mixture of at least two of ethyl cellulose, polyvinyl acetate, palmitic acid, polyethylene glycol, polypropylene glycol, polypropylene carbonate, and propylene diol.

16. The method of claim 13, wherein the solvent comprises at least one of water, methanol, ethanol, propanol, butanol, acetone, dimethyl ketone, propanone, methoxyethane, ethoxyethane, 1,2-dimethoxyethane, benzene, toluene, xylene, tetrahydrofuran, anisole, hexane, cyclohexane, carbon tetrachloride, methylene chloride, and chloroform.

17. The method of claim 12, wherein the application and the thermal treatment of the first metal precursor paste is performed one to 20 times, and the application and the thermal treatment of the second metal precursor paste is performed one to 20 times.

18. The method of claim 12, wherein the alkali metal precursor solution comprises at least one compound selected from fluoride, chloride, hydroxide, bromide, iodide, nitrate, perchlorate, carbonate, and sulfate compounds of an alkali metal.

19. The method of claim 12, wherein the alkali metal precursor solution comprises at least one solvent selected from water, methanol, ethanol, propanol, butanol, acetone, dimethyl ketone, propanone, methoxyethane, ethoxyethane, 1,2-dimethoxyethane, benzene, toluene, xylene, tetrahydrofuran, anisole, hexane, cyclohexane, carbon tetrachloride, methylene chloride, and chloroform.

20. The method of claim 12, wherein the application is performed using at least one method selected from printing, spin coating, roll-to-roll coating, slot die coating, bar coating, and spray coating.

21. A method of fabricating a chalcopyrite compound-based thin film, the method comprising:
applying a metal precursor paste onto a substrate and thermally treating the applied metal precursor paste to form a metal oxide thin film; and
thermally treating the metal oxide thin film under an atmosphere of a sulfur precursor in a gas state, a selenium precursor in a gas state, or a mixture thereof,
wherein the metal precursor paste comprises at least one Group IB metal precursor, at least one Group IIIA metal precursor, or a mixture thereof; and an alkali metal or an alkali metal precursor.

22. A method of fabricating a chalcopyrite compound-based thin film, the method comprising:
applying a first metal precursor paste onto a substrate and thermally treating the applied first metal precursor paste to form a first metal oxide thin film;
applying a second metal precursor paste onto the first metal oxide thin film and thermally treating the applied second metal precursor paste to form a second metal oxide thin film; and
thermally treating a stack of the first metal oxide thin film and the second metal oxide thin film under an atmosphere of a sulfur precursor in a gas state, a selenium precursor in a gas state, or a mixture thereof,
wherein the first metal precursor paste and the second metal precursor paste each independently comprise at least one Group IB metal precursor, at least one Group IIIA metal precursor, or a mixture thereof, and
the second metal precursor paste further comprises an alkali metal precursor.
